(19) United States
(12) Patent Application Publication
(10) Pub. No.: US 2011/0223766 A1
(43) Pub. Date: Sep. 15, 2011

(54) METHOD AND APPARATUS FOR MANUFACTURING SEMICONDUCTOR DEVICE

(75) Inventors: Yasushi Kobayashi, Kawasaki (JP); Yoshihiro Nakata, Kawasaki (JP); Yuichi Minoura, Kawasaki (JP)

(73) Assignee: FUJITSU LIMITED, Kawasaki-shi (JP)

(21) Appl. No.: 13/112,579

(22) Filed: May 20, 2011

Related U.S. Application Data
(63) Continuation of application No. PCT/JP2008/003642, filed on Dec. 8, 2008.

(51) Int. Cl. H01L 21/311; H01L 21/31; H01L 21/306; C23C 16/50

(52) U.S. Cl. 438/694; 438/778; 438/706; 118/723 R; 118/723 FE; 257/E21.24; 257/E21.249; 257/E21.219

(57) ABSTRACT

A method for manufacturing a semiconductor device includes: exposing an insulating film including a siloxane bond to an energy beam or plasma; and exposing the insulating film to a gas (excluding N₂ and H₂O gases) including at least one element selected from the group consisting of hydrogen, carbon, nitrogen and silicon, as an constituent element, wherein, in the exposing to the gas, after a relative permittivity of the insulating film descends by the exposing the insulating film to the gas, the exposing is completed before a time point when the relative permittivity of the insulating film first ascends.

### CROSS-REFERENCE TO RELATED APPLICATIONS

This application is a continuation of International Application No. PCT/JP2008/003642, filed on Dec. 8, 2008, now pending, herein incorporated by reference.

### FIELD

The embodiments discussed herein are relates to a method and an apparatus for manufacturing a semiconductor device.

### BACKGROUND

With the progress of a fine-structured semiconductor element, a wiring gap becomes narrow and inter-wire capacitance becomes increased. In recent years, such a kind of increased inter-wire capacitance greatly affects the operation speed of the semiconductor device. In particular, the inter-wire capacitance seriously affects the operation speed of a semiconductor device having a wiring gap of 0.1 μm or less.

In recent years, in order to reduce the inter-wire capacitance, a trial has been actively made to reduce the relative permittivity of an interlayer insulating film having buried wiring.

The conventional interlayer insulating film is a silicon oxide film formed by the thermal CVD (chemical vapor deposition) or the plasma CVD. Generally, such a silicon oxide film has a relative permittivity of about 4.1.

In contrast, in recent years, a technique has been developed to form an insulating film having a relative permittivity of 2.7 or lower, by sintering a coating film which is formed by coating a liquid composition, including a silicon compound, on a semiconductor substrate.

In the above coating film sintering process, each Si—OH group (silanol) forming the silicon compound (or an intermediate formed by a reaction between the silicon compound and the solvent thereof) mutually forms a siloxane bond (Si—O—Si bond) by a dehydration reaction. The insulating film is formed by use of the above siloxane bond as a main skeleton.

Generally, the atomic density of such an insulating film is small. Further, it is possible to form a large amount of nano-sized holes in the insulating film by use of a specific liquid composition. Such an insulating film has a low permittivity, and however, the mechanical strength is low. Accordingly, there exists a problem in such an insulating film that undesirably the insulating film is peeled off when the chemical mechanical polishing (CMP) is performed thereon to form Cu wirings.

In order to solve the above problem, a method has been proposed such that the above-mentioned coating film is sintered while being irradiated with an electron beam. According to this method, a molecular chain and a group, which are not cut by the thermal energy of sintering, are cut, and a bridging reaction is promoted. As a result, a rigid network of constituent atoms is formed in the insulating film, so that the mechanical strength of the insulating film is enhanced.

According to the above-mentioned method, a portion of bonds cut by the irradiation of the electron beam are left in the insulating film. Such an unpaired bond (dangling bond) is chemically active. In particular, a Si dangling bond easily reacts with atmospheric moisture (H₂O), so as to form a Si—OH group, according to the chemical formula described below. Such a Si-OH group increases the relative permittivity of the insulating film.

[Chemical formula 1]

≡Si·+H—HO →≡Si—HO+H (1)

As such, the insulating film which is irradiated with the electron beam involves a problem such that the relative permittivity is increased by the absorption of atmospheric moisture. In order to avoid such an increase of the relative permittivity, there has been proposed a method of exposing the insulating film to a hydrogen gas, a gas including halogen (for example, NF₃ gas), or an organic Si gas including silanol, during the irradiation, or after the irradiation, with the electron beam. The above exposure is performed for a period of 30 minutes.

According to the above method, it is possible to avoid the increase of the relative permittivity because the Si dangling bonds are terminated by the reaction with the NF₃ gas etc., according to the following chemical formula (2).

[Chemical formula 2]

≡Si·+F→≡Si−F (2)

Patent document 1: the official gazette of the Japanese Laid-open Patent Publication No. 2002-334873.
Patent document 2: the official gazette of the Japanese Laid-open Patent Publication No. 2004-153147.

### SUMMARY

According to an first aspect of the embodiments, a semiconductor device manufacturing method includes: irradiating an insulating film including a siloxane bond with an energy beam or plasma; and exposing the insulating film to a gas including at least one element selected from the group consisting of hydrogen, carbon, nitrogen and silicon excluding N₂ or H₂O gases, wherein said exposing the insulating film to the gas is finished before a time point when a relative permittivity of the insulating film first ascends after the relative permittivity descends by said exposing the insulating film to the gas.

According to an second aspect of the embodiments, a semiconductor device manufacturing apparatus includes: a processing room including a generation device configured to generate an energy beam or plasma to which an insulating film is irradiated; and a gas introduction device configured to introduce a gas including at least one element selected from the group consisting of hydrogen, carbon, nitrogen and silicon excluding N₂ or H₂O gases to the processing room, wherein the gas introduction device is configured to finish introducing the gas before a time point when a relative permittivity of the insulating film first ascends after the relative permittivity of the insulating film descends.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF THE DRAWINGS

FIG. 1 is a diagram illustrating relationship between the relative permittivity of a porous insulating film, on which dangling bond termination processing is performed, and a processing time.

FIG. 2 is a table describing the physical properties of the insulating film exposed to a hydrogen gas etc. after insulating film denaturation processing (part 1).

FIG. 3 is a table describing the physical properties of the insulating film exposed to a hydrogen gas etc. after insulating film denaturation processing (part 2).

FIG. 4 is a diagram illustrating relationship between the relative permittivity of the porous insulating film, on which dangling bond termination processing is performed, and a gas pressure used in the processing.

FIG. 5 is a diagram illustrating the configuration of the manufacturing apparatus to be used in the embodiment 1.

FIG. 6A is a process cross section diagram illustrating the semiconductor device manufacturing method according to the embodiment 1 (part 1).

FIG. 6B is a process cross section diagram illustrating the semiconductor device manufacturing method according to the embodiment 1 (part 2).

FIG. 6C is a process cross section diagram illustrating the semiconductor device manufacturing method according to the embodiment 1 (part 3).

FIG. 6D is a process cross section diagram illustrating the semiconductor device manufacturing method according to the embodiment 1 (part 4).

FIG. 6E is a process cross section diagram illustrating the semiconductor device manufacturing method according to the embodiment 1 (part 5).

FIG. 6F is a process cross section diagram illustrating the semiconductor device manufacturing method according to the embodiment 1 (part 6).

FIG. 6G is a process cross section diagram illustrating the semiconductor device manufacturing method according to the embodiment 1 (part 7).

FIG. 6H is a process cross section diagram illustrating the semiconductor device manufacturing method according to the embodiment 1 (part 8).

FIG. 6I is a process cross section diagram illustrating the semiconductor device manufacturing method according to the embodiment 1 (part 9).

FIG. 6J is a process cross section diagram illustrating the semiconductor device manufacturing method according to the embodiment 1 (part 10).

FIG. 6K is a process cross section diagram illustrating the semiconductor device manufacturing method according to the embodiment 1 (part 11).

FIG. 6L is a process cross section diagram illustrating the semiconductor device manufacturing method according to the embodiment 1 (part 12).

FIG. 6M is a process cross section diagram illustrating the semiconductor device manufacturing method according to the embodiment 1 (part 13).

FIG. 6N is a process cross section diagram illustrating the semiconductor device manufacturing method according to the embodiment 1 (part 14).

FIG. 7 is a table illustrating the properties of the semiconductor device manufactured under a variety of modified conditions of the dangling bond termination processing (part 1).

FIG. 8 is a table illustrating the properties of the semiconductor device manufactured under a variety of modified conditions of the dangling bond termination processing (part 2).

FIG. 9 is a diagram illustrating relationship between the temperature of dangling bond termination processing and the defect rate by stress migration.

FIG. 10 is a diagram illustrating the configuration of the manufacturing apparatus to be used in the embodiment 2.

### DESCRIPTION OF EMBODIMENTS

Hereinafter, preferred embodiments of the present invention will be described by reference to the drawings.

The semiconductor device in recent years has a lamination of a multiplicity of interlayer insulating films. Therefore, if long-time dangling bond termination processing is performed as in the above-mentioned proposal, the processing time is accumulated so that the manufacturing time of the semiconductor device becomes longer. This causes degradation of semiconductor device productivity.

According to the embodiments, it is possible to suppress the increase of permittivity of the insulating film, caused by processing such as electron beam irradiation to enhance the mechanical strength, in short-time processing.

By the way, in the method described earlier, the electron beam irradiation and the exposure to the NF₃ gas etc. are performed simultaneously. Therefore, even if the bond cut by the electron beam irradiation is once terminated by the exposure to the gas, the bond is cut again in some cases. Therefore, it is considered that, unless the insulating film is exposed to the gas for a long time, it is not possible to form the insulating film having no dangling bond.

According to the aforementioned consideration, if the exposure to the gas is performed after the electron beam irradiation, the insulating film having no dangling bond is to be formed in a short time.

Therefore, a trial was made to suppress the increase of permittivity by exposing the insulating film to a hydrogen gas etc. for a short time after electron beam irradiation is performed.

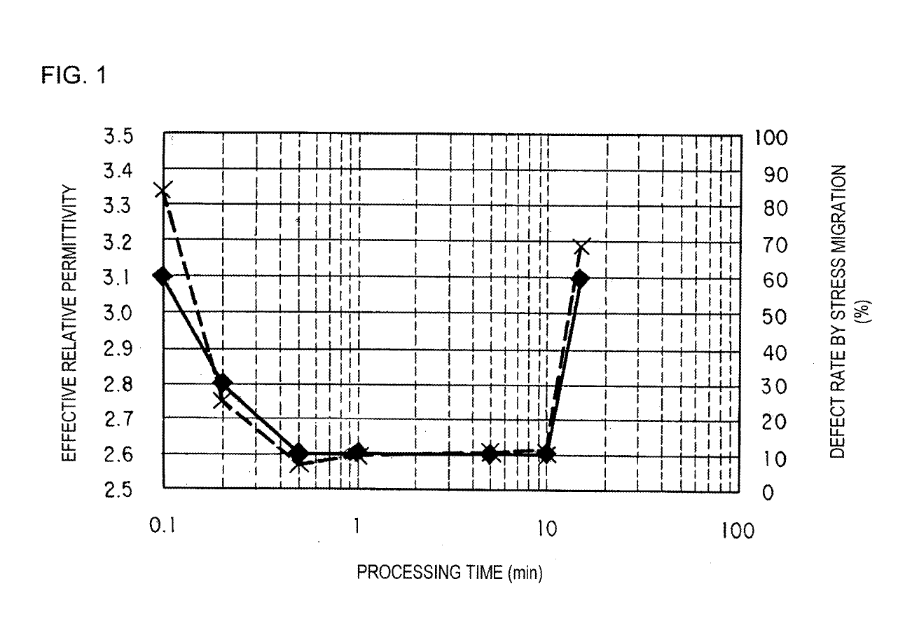

FIG. 1 is a diagram illustrating relationship between the processing time to expose the insulating film to the gas after the electron beam irradiation and an effective relative permittivity of the insulating film. The horizontal axis represents the processing time, and the left vertical axis represents the effective relative permittivity. Here, an effective relative permittivity is a relative permittivity calculated on the basis of an inter-wire capacitance, and is greater than the actual relative permittivity by about 0.3.

The used gas is ethylene, and a gas pressure at that time is 1.0 Pa. In FIG. 1, not only the variation of the effective relative permittivity which is indicated by the solid line, the variation of a defect rate by stress migration, which is indicated by the broken line, is depicted. As to the details of experiment conditions and so on. and the variation of the defect rate by stress migration, descriptions will be given in the explanation below.

As depicted in FIG. 1, the effective relative permittivity decreases for a period of time (in case of the present embodiment, up to 0.5 minutes) after the insulating film is exposed to the gas, and thereafter, maintains to have a substantially constant value. Then, the effective relative permittivity abruptly increases if the processing time becomes long. From such a result, the inventors of the present invention obtain a knowledge such that the permittivity does not become low if the insulating film exposure time to the hydrogen gas etc. is either too long or too short, and instead, the permittivity becomes low only within a certain time range.

The semiconductor device manufacturing method according to the present embodiment provides a semiconductor device manufacturing method which suppresses the increase of permittivity of the insulating film caused by the electron beam irradiation and so on in a short time, on the basis of such a knowledge.

More specifically, according to the semiconductor device manufacturing method of the present embodiment, after the relative permittivity of the insulating film descends (decreases), the gas exposure to the insulating film is completed before the time point when the relative permittivity first ascents (increases).

With such a method, it is possible to suppress the increase of permittivity of the insulating film, caused by the processing (electron beam irradiation, for example) to enhance the mechanical strength of the insulating film, in a short time.

The following description is the details of the trial which has led to the acquisition of the aforementioned knowledge.

The manufacturing procedure of samples used for the measurement is as follows.

First, by means of a spin coat method, a liquid composition (commercial product name: Ceramate NCS, manufactured by Catalysts & Chemicals Ind. Co., Ltd) including a silicon compound is coated on a Si substrate. The above silicon compound contains Si, O, C and H as principal components.

Further, the above silicon compound is a substance obtained by hydrolyzing tetraalkylorthosilicate (TAOS) and alkoxysilane (AS) under the existence of tetraalkylammoniumhydroxide (TAAOH), for example.

Here, the above alkoxysilane is represented by the following general formula (I).

XₙSi(OR)₄₋ₙ (I)

Here, X represents any one of hydrogen atom, fluorine atom, alkyl group with the carbon number of 1 to 8, fluorine-substituted alkyl group, aryl group and vinyl group. Also, R represents any one of hydrogen atom, alkyl group with the carbon number of 1 to 8, aryl group and vinyl group. Further, n is an integer of 0 to 3.

Next, on the above film coated on the Si substrate, heating processing is performed at 100° C. for approximately 5 minutes. By this heating processing, an organic solvent in the coated film is vaporized.

Next, the above film is sintered at 400° C. for appropriately 10 minutes. By this sintering, an insulating film having a siloxane bond (Si—O—Si bond) is formed. This insulating film is of low density. Moreover, micropores having diameters of 2 nm or less are formed in the insulating film. By this, a low relative permittivity having a value of 2.5 or less is achieved. Hereafter, such an insulating film is referred to as a porous insulating film.

On the porous insulating film thus formed, having a thickness of 160 nm, processing to cut the bond thereof is performed (hereafter referred to as insulating film denaturation processing). As an energy beam used for the insulating film denaturation processing, ultraviolet irradiation or plasma other than the known electron beam irradiation was used.

The details of each of the insulating film denaturation processing are described below.

The conditions of the electron beam irradiation are as follows.

The dosage and the energy of the electron beam are 40 μC/cm².min and 5 key, respectively. Also, the irradiation time is 10 minutes. While the electron beam irradiation is carried out, heating of the substrate is not performed in particular.

The conditions of the ultraviolet irradiation are as follows.

The luminance and the wavelength of the ultraviolet ray are 300 mW/cm² and 200-400 nm, respectively. Also, the irradiation time is 10 minutes. Additionally, the ultraviolet irradiation is performed in vacuum without particularly heating the substrate.

The conditions of plasma exposure are as follows.

The plasma used for the exposure is O₂ plasma which is generated by applying a radio frequency wave (13.56 MHz) of 200 W to an O₂ gas having a pressure of 10 Pa. The exposure time is 3 minutes, and heating of the substrate is not performed in particular.

The insulating film, on which the insulating film denaturation processing described above is performed, is exposed to a gas such as a hydrogen gas, in a state that the insulating film is kept shut out of the atmosphere.

The used gas is hydrogen, methane, ethylene, ammonia, silane and hexamethyldisilazane. The exposure time to the gas is 0.1 to 15 minutes. The substrate temperature at that time is room temperature (25° C.) to 400° C.

The following description relates to the measurement of the physical properties performed on the sample manufactured by the above procedure.

The examined physical properties are relative permittivity, leak current density, modulus of elasticity, relative proportion of the dangling bond, and internal stress difference.

Relative permittivity

The relative permittivity is calculated on the basis of the capacitance of a capacitor for evaluation which is formed on the insulating film of evaluation target, and the thickness of the insulating film.

The evaluation capacitor is made by forming a Au electrode, having a diameter of 1 mm, on the insulating film of evaluation target, and further, by forming an ohmic electrode on the back face of the Si substrate on which the insulating film is formed. The sample for the measurement of the effective relative permittivity illustrated in FIG. 1 will be described later in the embodiment 1.

The capacitance measurement is performed using an impedance measuring instrument (which is so-called an LCR meter) to measure impedance by applying an alternative current, having a frequency of 1 MHz and an effective value of 1 V, to the measurement sample. Meanwhile, the measurement of the film thickness of the insulating film is performed by means of spectroscopic ellipsometry.

Now, when the dangling bonds are formed in the insulating film, the insulation characteristic of the insulating film is deteriorated. The reason is that the dangling bond concerned, or a Si—OH group formed by the reaction between the dangling bond and atmospheric moisture, produces an energy level which causes a leak current in a band gap. Therefore, the leak current density is added to the evaluation items.

Leak current density

The leak current density is calculated on the basis of the leak current of the above-mentioned evaluation capacitor and the thickness of the insulating film. The measurement of the leak current is performed using a voltage-current measuring instrument (so-called I-V meter), by measuring the current which flows in the sample while increasing (or decreasing) the voltage in the range of 0 to 20 V at the step of 0.02 V. The leak current density to be evaluated is a value calculated from the leak current when the electric field of 0.2 MV/cm is applied to the insulating film.

Modulus of elasticity

The higher the modulus of elasticity of the film is, the greater the mechanical strength of the insulating film becomes. Therefore, as an index of the mechanical strength, the modulus of elasticity is also added to the evaluation items.

The measurement of the modulus of elasticity is performed by means of a continuous stiffness measurement method using a nano indenter. The continuous stiffness measurement is performed by operating an indenter at a pushing speed of 0.5 nm/sec with a resonant frequency of 25 Hz. The indenter in use is a Berkovic indenter having a radius of curvature of 0.2 μm. Further, the calculation of the modulus of elasticity is performed by use of data obtained when the indenter is pushed to a depth 0.07 times as deep as the thickness of the sample.

By using electron spin resonance equipment, the measurement of the dangling bond density is performed by irradiating the sample with a microwave, having a frequency of 9.17 GHz, with output power 1 mW under room temperature. The magnetic field sweep time is 1 sec, and as a standard sample, Mn²⁺/MgO is used. The measurement is performed immediately after the sample is taken out to the atmosphere.

Relative proportion of the dangling bond

The sample for use to measure the dangling bond density is obtained by that the insulating film to be evaluated is peeled off from the substrate and powdered. By using this sample, an amount of the dangling bond per unit weight (dangling bond density) is obtained.

The relative proportion of the dangling bond for use as an evaluation item is a value obtained by normalizing the above obtained dangling bond density by a dangling bond density of a sample on which the insulating film denaturation processing is not performed.

Internal stress difference

On the occurrence of an internal stress on the insulating film, the stress migration of wiring covered with the interlayer insulating film is accelerated. Accordingly, the internal stress difference on the insulating film before and after the insulating film denaturation processing is also added to the evaluation items.

The measurement of the internal stress of the insulating film is performed by use of a stress measuring device. The internal stress difference as the evaluation item is a difference between the internal stress of a sample on which the insulating film denaturation processing is not performed and the internal stress of the sample on which the insulating film denaturation processing is performed.

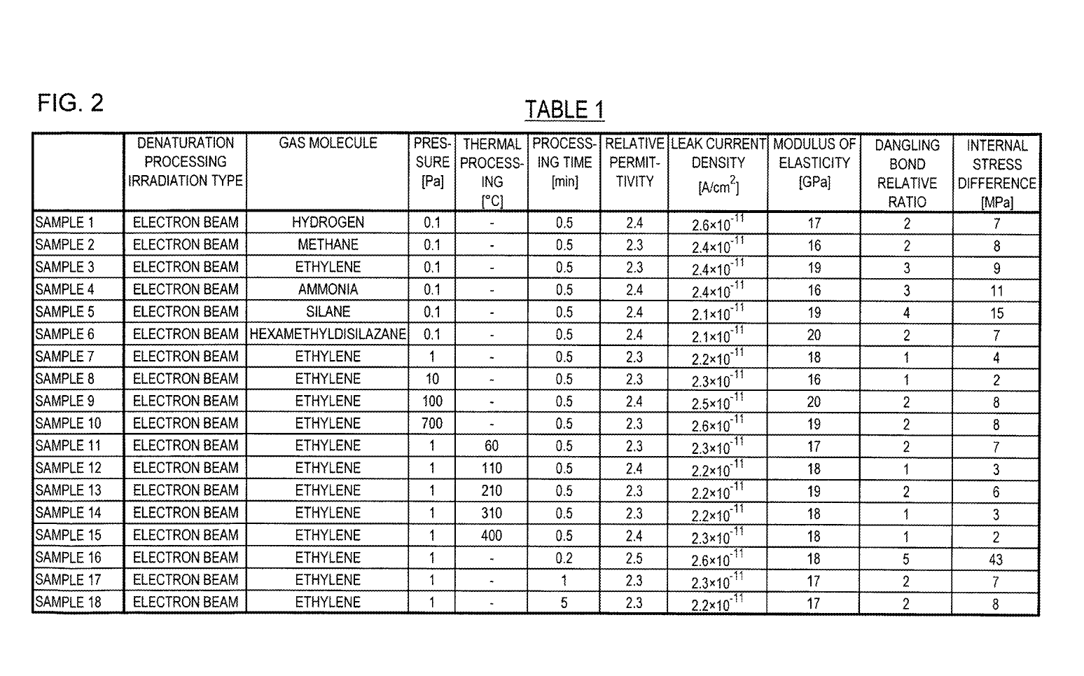

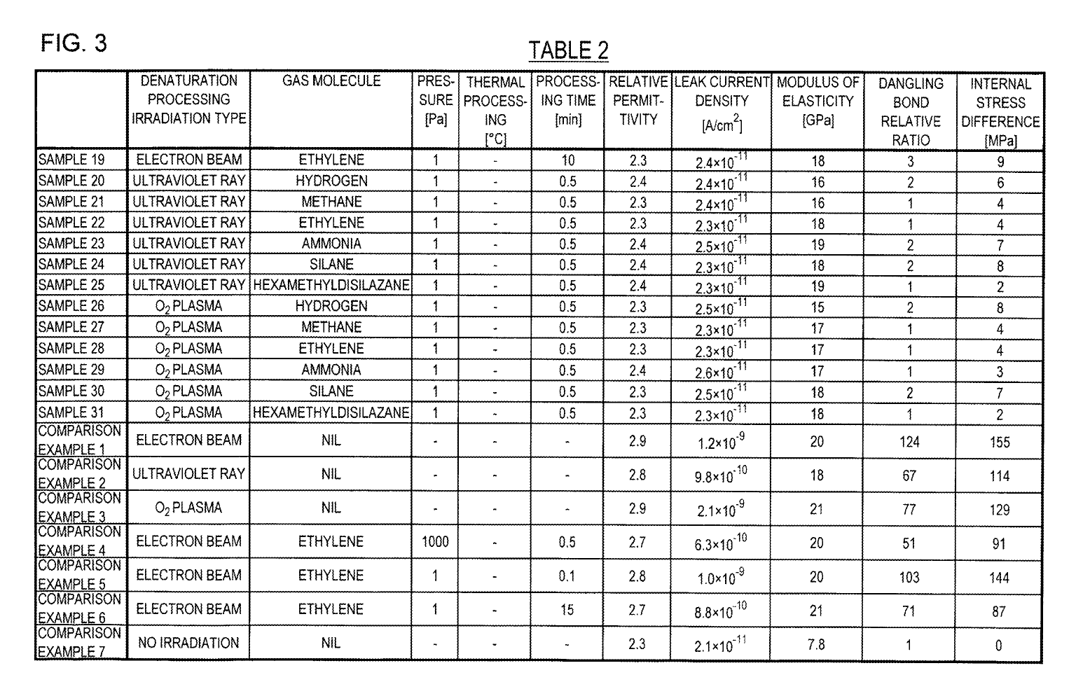

FIGS. 2 and 3 are tables in which the physical properties of the insulating film thus examined are collected.

In the respective columns of the tables, the manufacturing conditions of the insulating film of which physical properties have been examined, or the measured values of the physical properties are described.

In the first column, each sample name is described. The samples 1 to 31 are samples of which exposure (hereafter referred to as dangling bond termination processing) to the hydrogen gas etc. is found effective. The comparison examples 1 to 7 are samples for comparison or samples on which the dangling bond termination processing is not effective.

In the second column, each type of the insulating film denaturation processing is described. “Electron beam”, “ultraviolet ray” and “O₂ plasma” described in the second column signify electron beam irradiation, ultraviolet irradiation and exposure to plasma, respectively.

In the third column, each gas type used in the dangling bond termination processing is described. In the fourth column, each pressure of the gas being in exposure is described. In the fifth column, each temperature of the samples when the dangling bond termination processing is performed thereon is described. Here, the description of “-” signifies that the dangling bond termination processing is executed without heating the sample. In the sixth column, each time of the dangling bond termination processing (processing time) is described.

In the seventh column and after, the physical properties of the insulating film obtained from the above-mentioned measurement results are described.

A comparison example 7 relates to a sample on which neither the insulating film denaturation processing nor the dangling bond termination processing is performed. As described in Table 2, the relative permittivity of the sample concerned is as small as 2.3. Also, the leak current is as small as 2.1×10⁻¹¹ A/cm².

Comparison examples 1 to 3 relate to a sample on which only the insulating film denaturation processing is performed, but the dangling bond termination processing is not performed.

In regard to samples on which any of the electron beam irradiation, ultraviolet irradiation and plasma exposure is performed, the relative proportion of the dangling bond greatly increases to 67 to 124. Also, the relative permittivity ascends to 2.8 to 2.9. Further, the leak current density also increases to 9.8×10⁻¹⁰ A/cm² to 2.1×10⁻⁹ A/cm², which is 50 to 100 times as large as in the case of the comparison example 7 on which the insulating film denaturation processing is not performed. Meanwhile, the modulus of elasticity, which is an index of the mechanical strength, is 18 to 21 GPa, which is an increase of approximately 2 to 3 times. Meanwhile, the internal stress difference greatly increases to 114 to 155 MPa as well.

The above facts indicate that the dangling bonds are generated in the insulating film by the insulating film denaturation processing, and as a result, the relative permittivity, the leak current and the internal stress are increased. Further, the above facts indicate that the mechanical strength of the insulating film is enhanced by the insulating film denaturation processing.

As described earlier, it has been considered that the increase of relative permittivity by electron beam irradiation is caused by the generation of the Si—OH bond. However, even in a sample exposed to the atmosphere for a short time, in which a multiplicity of dangling bonds have not reacted with atmospheric moisture yet, the increase of both the relative permittivity and the leak current is found. Accordingly, it is considered that the dangling bond itself contributes to the increase of the relative permittivity and the increase of the leak current.

Comparison examples 4 to 6 are the cases of samples in which no effect of the dangling bond termination processing is produced. As described in Table 2, the dangling bond termination processing is performed on the above samples, and however, the relative proportion of the dangling bond in these samples is increased to 51 to 103. Also, the relative permittivity ascends to 2.7 to 2.8. Further, the leak current density is increased to 6.3×10⁻¹° A/cm² to 1.0×10⁻⁹ A/cm². The above values are 30 to 50 times as large as the leak current density of the comparison example 7 in which the insulating film denaturation processing is not performed. Also, the internal stress difference is increased to 87 to 144 MPa. Additionally, the modulus of elasticity, which is an index of the mechanical strength, is also increased approximately 2.6 times.

The time of the dangling bond termination processing performed on each comparison example 4-6 widely ranges from 0.1 to 15 minutes. Also, each gas pressure used in the dangling bond termination processing ranges from 1 to 1,000 Pa. Nevertheless, the effect of the dangling bond termination processing was not recognized.

Meanwhile, the inventors of the present invention found out a case that the dangling bonds are terminated by the gas exposure (dangling bond termination processing) with a low gas pressure for an extremely short time (for example, refer to sample 7).

In general, it is considered that the longer the dangling bond termination processing time is, or the higher the gas pressure used in the processing is, the more dangling bonds are terminated.

The above-mentioned fact does not coincide with such a general estimation.

Accordingly, the inventors of the present invention have examined the physical properties of samples which were manufactured by variously modifying the conditions of the dangling bond termination processing and the types of the gas for use.

Samples 1 to 31 are those in which the effect of the dangling bond termination processing appeared.

First, as described in Tables 1 and 2, the dangling bond termination processing is effective, irrespective of the used gases described earlier. More specifically, each relative proportion of the dangling bond in the samples 1 to 31 is as low as 1 to 3, which is of the same range as the comparison example 7 in which the insulating film denaturation processing is not performed. Also, each relative permittivity of the samples 1 to 31 is roughly 2.3 to 2.5, which is of the same range as the comparison example 7 in which the insulating film denaturation processing is not performed. Further, each leak current and internal stress difference in the samples 1 to 30 is in the same range as the comparison example 7 in which the insulating film denaturation processing is not performed. In contrast, each modulus of elasticity in the samples 1 to 31 is 15 to 20 GPa, which is appropriately as high as the comparison examples 1 to 3 where only the insulating film denaturation processing is performed.

The above-mentioned results indicate that, the increases of the relative permittivity, the leak current and the internal stress caused by the insulating film denaturation processing are suppressed by the termination of the dangling bonds caused by the aforementioned variety of types of gases, and by the exposure to the gases (dangling bond termination processing).

The reason that the termination processing of the dangling bond using the variety of gases is effective is considered that the dangling bond of Si is exceedingly active.

Here, the gases producing effective dangling bond termination processing are gases having at least one element selected from the group consisting of hydrogen, carbon, nitrogen and silicon, as constituent element. Such gases are chemically active, different from inactive gases like Ar.

However, although a nitrogen gas contains nitrogen as constituent element, the nitrogen gas does not terminate the Si dangling bond because of being inactive. Also, it is not possible to use H₂O gas because Si—OH bond is generated.

In order to clarify conditions to produce effective dangling bond termination processing, the inventors of the present invention have compared the manufacturing conditions between the above samples and the above-mentioned comparison examples 4-6 in which the increase of the relative permittivity was not suppressed.

FIG. 1 is a diagram illustrating relationship between the time for the above-mentioned dangling bond termination processing and the effective relative permittivity of the insulating film. The solid line indicates the variation of the effective relative permittivity. The horizontal axis illustrates the processing time. The left vertical axis illustrates the effective relative permittivity.

The data in FIG. 1 are calculated from the capacitance of the wiring formed in the interlayer insulating film which was manufactured under the same conditions as the samples 7 and 16-19 and the comparison examples 5 and 6 (as to the structure of the samples, refer to the embodiment 1 described later).

Namely, the insulating film denaturation processing performed on the sample is electron beam irradiation. Also, the gas used in the dangling bond termination processing is ethylene. Further, the pressure of the ethylene gas is 1.0 Pa, and the sample temperature is room temperature (25° C.).

As illustrated in FIG. 1, by the gas exposure, the relative permittivity of the insulating film on which the insulating film denaturation processing is performed descends for 0.5 minute from the start. However, when the exposure to the gas exceeds 10 minutes, the relative permittivity abruptly increases.

It is considered that the reduction of the relative permittivity in the early period of the gas exposure is caused by that the dangling bonds are terminated by the used gas. In contrast, the increase of the relative permittivity by the long-time ethylene gas exposure is considered to be caused by that an active species (for example, ethylene from which one H is removed) produced by the dangling bond termination is increased in the atmosphere. If a large amount of such a species exists in the atmosphere, for example, H atom is removed from the Si—H bond forming the insulating film, and a new dangling bonds are formed.

Therefore, if the exposure to the gas (dangling bond termination processing) is stoped before the relative permittivity of the insulating film starts to increase, it is possible to stop the increase of the relative permittivity caused by the insulating film denaturation processing. Moreover, as illustrated in FIG. 1, it is possible to terminate most dangling bonds in a short time of 0.5 to 10 minutes.

The present manufacturing method of the semiconductor device is based on such a knowledge as described above.

The present semiconductor device manufacturing method includes a first process to expose an insulating film (for example, the above-mentioned porous insulating film) having a siloxane bond to an energy beam (for example, electron beam or ultraviolet ray) or plasma (for example, O₂ plasma). Here, the energy beam signifies a flow of particles having energy, such as accelerated electrons and photons. Further, the energy of such particles is larger than the energy for cutting the bond.

Also, the present semiconductor device manufacturing method includes a second process to expose the above-mentioned insulating film to a gas (excluding N₂ and H₂O gases; for example, ethylene) having at least one element selected from the group consisting of hydrogen, carbon, nitrogen and silicon, as constituent element.

Further, according to the present semiconductor device manufacturing method, in the above-mentioned second process, the exposure is completed before a time point when the relative permittivity of the insulating film first ascends, after the relative permittivity of the insulating film descends by the gas exposure to the insulating film (refer to FIG. 1).

For example, in the example illustrated in FIG. 1, it is considered that the descent of the relative permittivity is completed between 0.2 and 0.5 minute after the start of the gas exposure, and that the first ascent occurs 10 to 15 minutes after the start of the gas exposure. Accordingly, preferably, the exposure time is 0.5 minute or more and 10 minutes or less, and more preferably, 1 minute or more and 5 minutes or less.

Such an exposure time is remarkably short as compared to the gas exposure time of 30 minutes in the conventional method of irradiating the insulating film with an electron beam simultaneously with sintering. Therefore, according to the present semiconductor device manufacturing method, it is possible to suppress an increased permittivity of the insulating film, which is produced by processing (electron beam irradiation etc.) to enhance the mechanical strength, in a short time.

Therefore, according to the present semiconductor device manufacturing method, the productivity of the semiconductor device is improved.

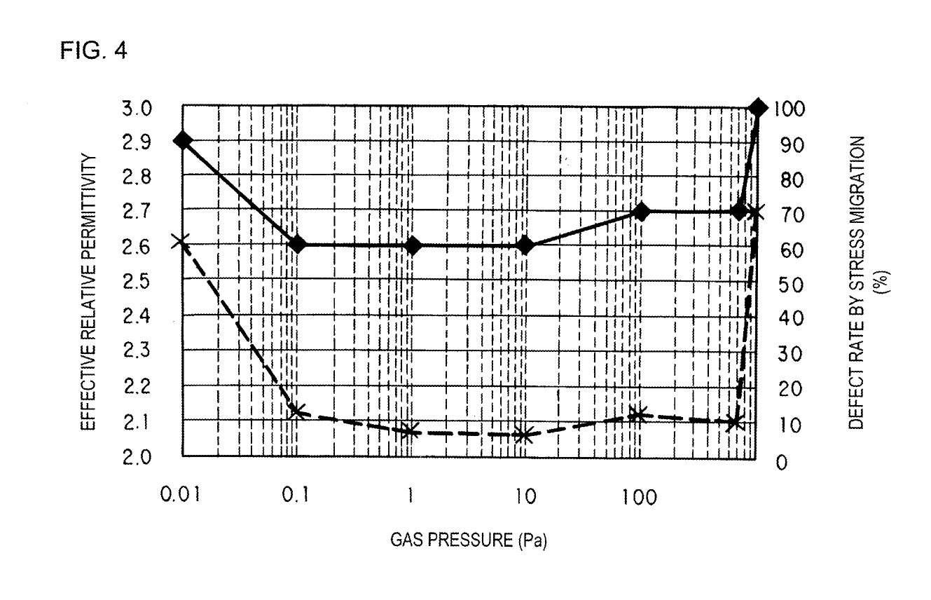

FIG. 4 is a diagram illustrating relationship between the effective relative permittivity of the insulating film, on which the termination processing is performed, and the gas pressure used in the termination processing. The horizontal axis illustrates the gas pressure used in the termination processing. The left vertical axis illustrates the effective relative permittivity of the insulating film. In FIG. 4, not only the variation of the effective relative permittivity of the insulating film, which is depicted with the solid line, the variation of the defect rate by stress migration is depicted with the broken line. The description of the stress migration is given in the embodiment described later.

The data in FIG. 4 are calculated from the capacitance of the wiring formed in the interlayer insulating film being manufactured under the same conditions as the samples 3 and 7-10 and the comparison example 4 (as to the details, refer to the embodiment described later).

Namely, the insulating film denaturation processing performed on the sample is electron beam irradiation. Also, the gas used in the dangling bond termination processing is ethylene. The exposure time to the ethylene gas is 0.5 minute, and the sample temperature is room temperature.

As illustrated in FIG. 4, the effective relative permittivity of the insulating film, on which the insulating film denaturation processing is performed, becomes 2.7 or less when being exposed to a gas having a pressure of 0.05 Pa or higher. However, when the gas pressure exceeds 700 Pa, the effective relative permittivity abruptly increases.

It is considered that the reduction of the relative permittivity in a low pressure region is caused by that the dangling bonds are terminated by the ethylene gas. In contrast, the increase of the relative permittivity in a high pressure region is considered to be caused by that an active species (for example, ethylene from which one H is removed) produced by the dangling bond termination is increased in the atmosphere, and a new dangling bonds are formed in the insulating film.

Here, preferably, the above-mentioned gas pressure in the exposure (the exposure of the insulating film to the ethylene gas etc.) is 0.05 Pa or more and 700 Pa or less, and more preferably, 0.1 Pa or more and 100 Pa or less, and further, most preferably, 1 Pa or more and 50 Pa or less (refer to FIG. 4).

Under the gas pressure having such a value, the gas exposure time for reducing the permittivity of the insulating film becomes remarkably short (for example, 0.5 minute), as compared to the gas exposure time (30 minutes) in the conventional method.

Therefore, according to the present semiconductor device manufacturing method, it is possible to suppress an increased permittivity of the insulating film, produced by the processing (electron beam irradiation etc.) to enhance the mechanical strength, in a short time. Therefore, according to the present semiconductor device manufacturing method, the productivity of the semiconductor device is improved.

Additionally, the gas for use in the above-mentioned second process is preferably any one gas selected from the group consisting of hydrogen, methane, ethylene, ammonia, silane and hexamethyldisilazane (refer to FIGS. 2 and 3).

### Embodiment 1

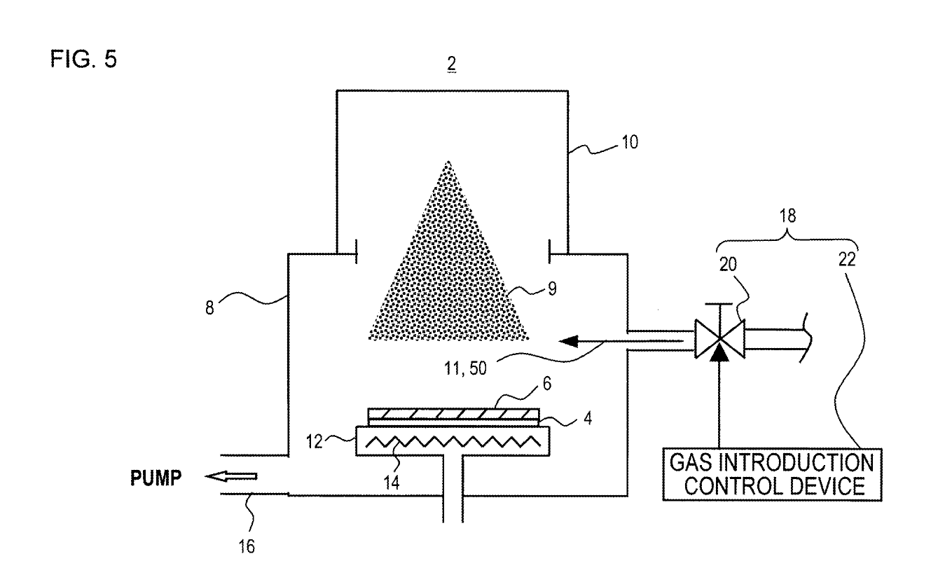

FIG. 5 is a diagram illustrating the configuration of a manufacturing apparatus 2 for use in the semiconductor device manufacturing method which will be explained according to the present embodiment.

The present manufacturing apparatus 2 includes a processing room 8 having a generation device 10 for generating an energy beam (for example, electron beam or ultraviolet ray), to which the insulating film 6 is exposed, in a state of being shut out of the atmosphere.

Further, the present manufacturing apparatus 2 includes a gas introduction device 18 for introducing a gas having at least one element selected from the group consisting of hydrogen, carbon, nitrogen and silicon (excluding nitrogen and H₂O gases) as constituent element, to the above processing room 8, and for completing the above introduction of the gas before the time point of the first ascent of the relative permittivity of the insulating film 6 after the relative permittivity descends.

More specifically, the processing room 8 includes the generation device 10 for irradiating the entire surface of the insulating film 6 with an electron beam 9. In the internal processing room 8, a sample support stage 12 is provided to mount a semiconductor substrate 4 thereon.

Such a sample support stage 12 is formed as a hot plate having a heating device 14 to enable heating the insulating film 6 which is formed on the semiconductor substrate 4.

The exhaust of the processing room 8 is performed via a vacuum exhaust outlet 16. Additionally, though not illustrated in the figure, on the downstream side of the vacuum exhaust outlet 16, on/off valve, pressure regulating device and exhaust pump (vacuum pump) are installed. Accordingly, the insulating film 6 may be exposed to the energy beam in a state that the air is ejected from the inside of the processing room 8.

Further, the present manufacturing apparatus 2 includes the gas introduction device 18 which introduces a predetermined gas to the above processing room 8 while the state of being shut out of the atmosphere is maintained, and completes the introduction of the gas after the relative permittivity of the insulating film 6 descends, before the time point when the relative permittivity first ascents. Here, the predetermined gas is a gas having at least one element selected from the group consisting of hydrogen, carbon, nitrogen and silicon (excluding N₂ and H₂O gases) as constituent element.

More specifically, as the predetermined gas, any one of the gases selected from the group consisting of hydrogen, methane, ethylene, ammonia, silane and hexamethyldisilazane is preferable.

Further, the gas introduction device 18 includes a valve 20 connected to a gas supply device (not depicted in the figure) which provides the above predetermined gas. Also, the gas introduction device 18 includes a gas introduction control device 22 for controlling the open and close of the valve 20. The gas introduction control device 22 completes the above gas introduction by closing the valve 20 after the relative permittivity of the insulating film 6 descends, before the time point when the relative permittivity first ascents.

Additionally, the generation device 10 may be a device for generating an electron beam (electron beam source), or a device for generating an ultraviolet ray (for example, high voltage mercury lamp).

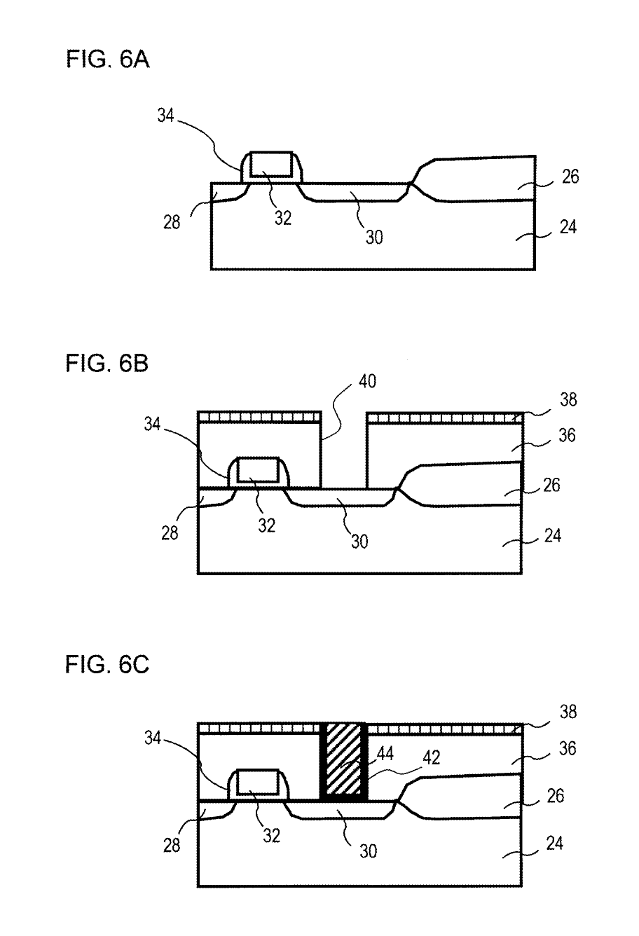

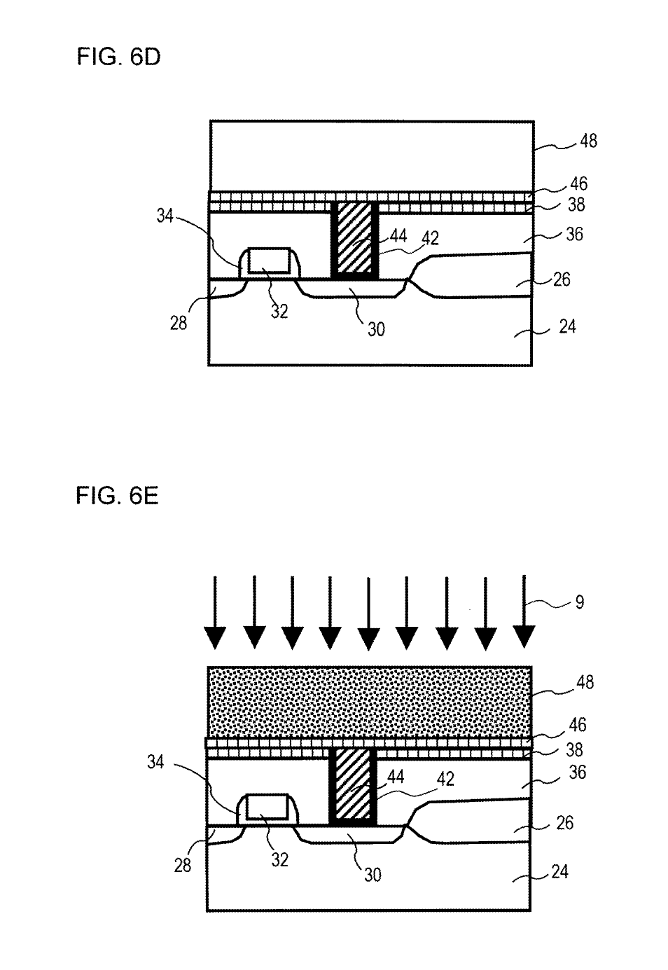

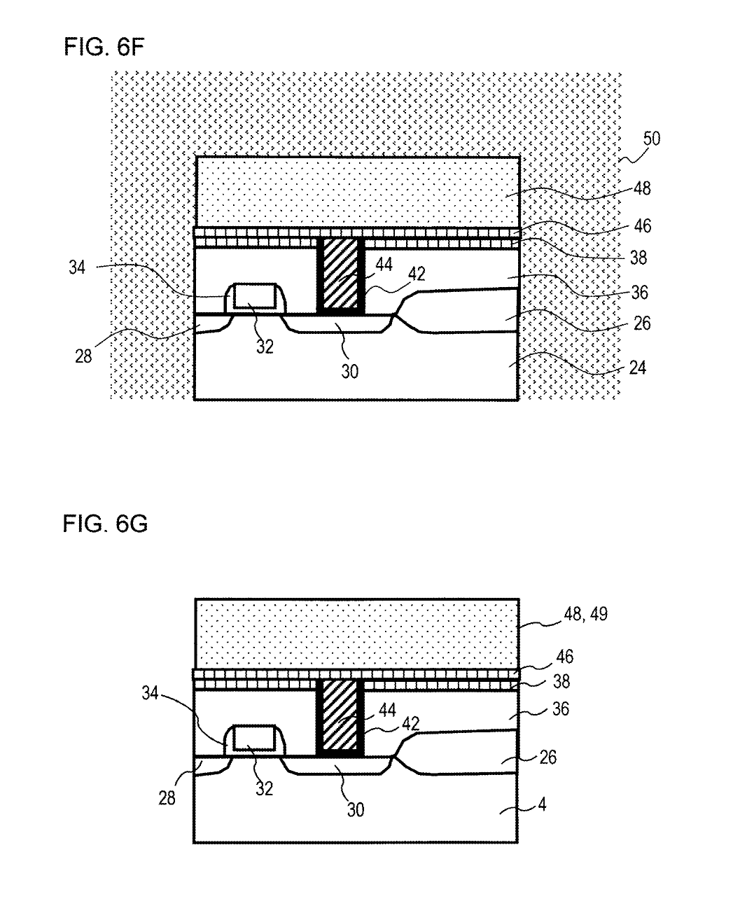

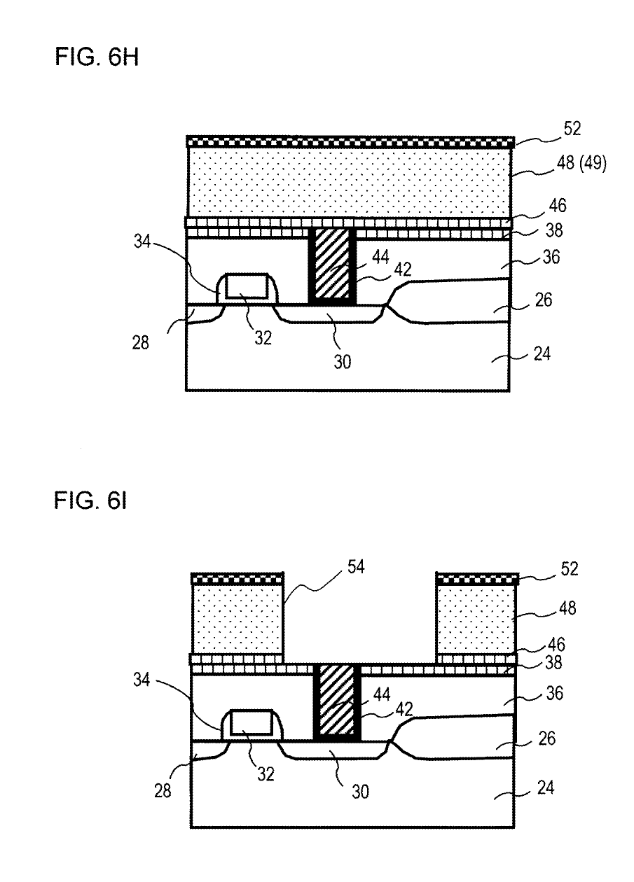

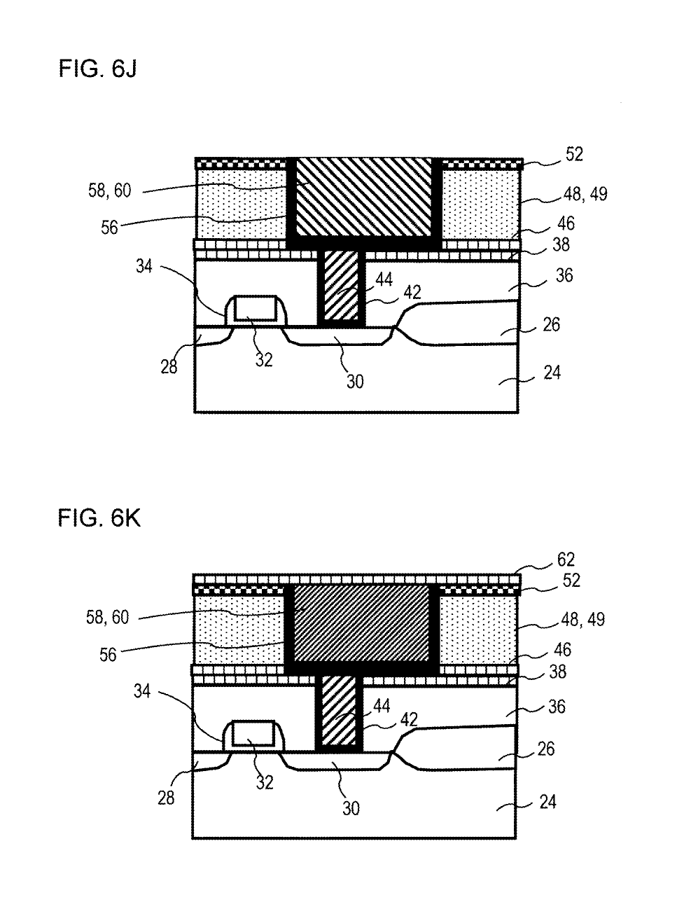

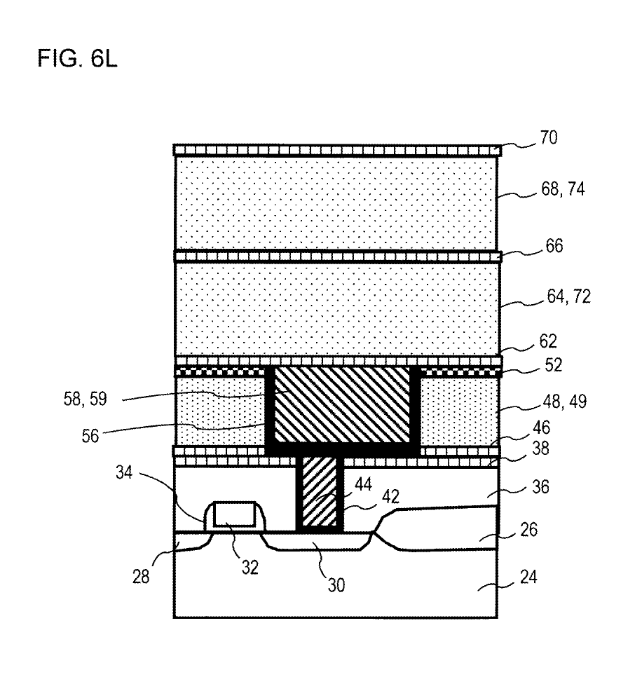

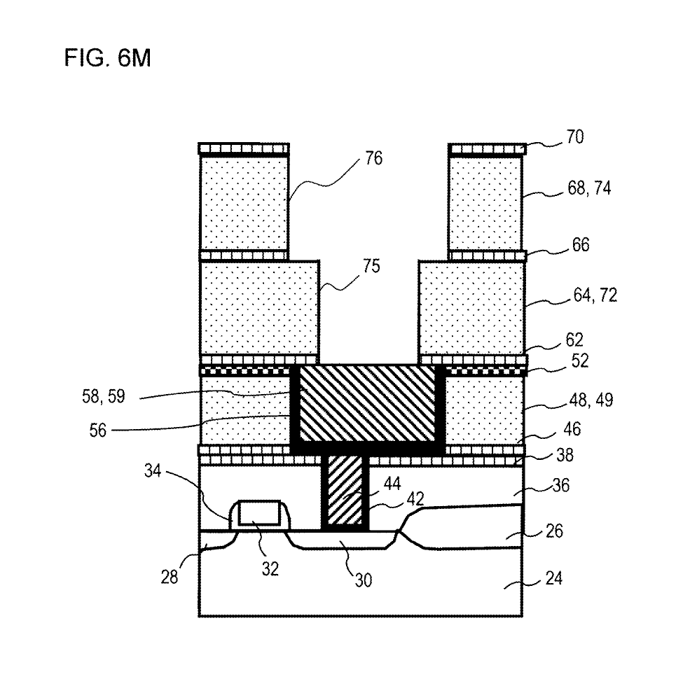

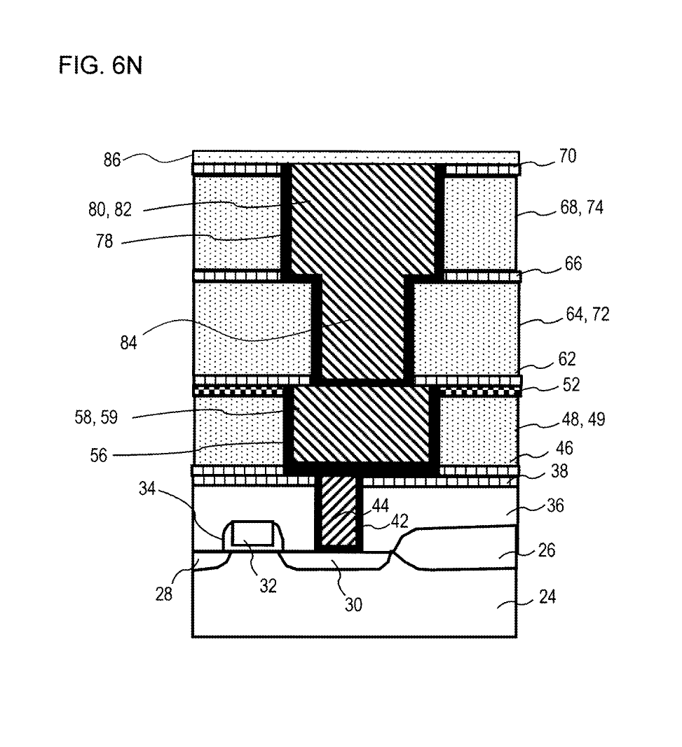

FIGS. 6A to 6N are process cross section diagrams illustrating the manufacturing method of the semiconductor device (for example, integrated circuit device for graphical use and microprocessor) according to the present embodiment.

First, on a silicon wafer 24, a plurality of transistors separated by an inter-element separation film 26 and each having source diffusion layer 28, drain diffusion layer 30 and gate electrode 32 are formed. The gate electrode 32 includes a sidewall silicon insulating film 34, and is formed on a gate oxide film (refer to FIG. 6A).

Next, on the Si wafer 24 having the transistor formed thereon, a SiO₂ film 36, which becomes a first interlayer insulating film, is formed by a P-CVD method (plasma chemical vapor deposition), for example. Thereafter, a stopper film 38 is formed on the SiO₂ film 36, and further, a contact hole 40 for producing an electrode is formed (refer to FIG. 6B).

Next, a TiO 42 having a thickness of 50 nm is formed inside the contact hole 40. Thereafter, using a mixed gas composed of a WF₆ gas and hydrogen as a material, the contact hole 40 is filled in with W. Further, the W deposited on the stopper film 38 is removed by the chemical mechanical polishing (CMP) at this time. By the above processes, a first conductor plug 44 is formed (refer to FIG. 6C).

Next, on the first conductor plug 44 and the stopper film 38, a SiC film having a thickness of 30 nm is formed by the chemical vapor deposition (CVD). Here, the SiC film 46 is a SiC:O:H film having both oxygen and hydrogen as constituent element

Next, based on a material of the aforementioned liquid composition (commercial product name: Ceramate NCS, manufactured by Catalysts & Chemicals Ind. Co., Ltd), a porous insulating film is formed on the first SiC:O:H film 46 (refer to FIG. 6D). The first porous insulating film 48 thus formed has a thickness of 160 nm, with a relative permittivity of 2.3. Also, the modulus of elasticity is 7.8 GPa. The material (liquid composition) of the porous insulating film and the formation procedure thereof are as described above.

Namely, the first porous insulating film 48 is an insulating film formed by coating a liquid composition including a silicon compound on a semiconductor substrate, and by sintering the above coated liquid composition.

As described above, the porous insulating film is an insulating film having a siloxane bond (Si—O—Si bond). In place of such a porous insulating film, it may also be possible to use another insulating film also having the siloxane bond.

Additionally, since the mechanical strength of the insulating film becomes particularly low in case that the relative permittivity of the insulating film is 2.7 or less, the merit of applying the present embodiment becomes great. Therefore, it is preferable if the relative permittivity of the above insulating film is 2.7 or less, and more preferable if it is 2.5 or less. Here, the relative permittivity of a general insulating film is 2.0 or more. Further, the lower the relative permittivity is, the lower the mechanical intensity becomes. Therefore, preferably, the relative permittivity of the above insulating film is 2.0 or more, and more preferably, 2.3 or more.

Next, on the first porous insulating film 48, the insulating film denaturation processing by electron beam irradiation is performed (refer to FIG. 6E).

First, a Si wafer 24 having the porous insulating film 48 formed thereon is mounted on a sample support stage 12 of the manufacturing apparatus 2 described by reference to FIG. 5. Thereafter, the internal of processing room 8 is exhausted via the vacuum exhaust outlet 16, so that the vacuum is obtained.

Next, the porous insulating film 48 is irradiated with the electron beam 9 generated by the generation device 10. The doze and the energy of the electron beam are 40 μC/cm²·min and 5 keV, respectively. Also, the irradiation time of the electron beam is 10 minutes.

By the above electron beam irradiation, in the state of being shut out of the atmosphere, the bond of the first porous insulating film 48 having the siloxane bond is cut. The above cut bond is rebonded, and a rigid network of constituent atoms is formed. As a result, the mechanical strength of the first porous insulating film 48 is increased to 20 GPa. At the same time, the relative permittivity of the first porous insulating film 48 is increased to 2.9 (the effective relative permittivity of 3.2).

The above-mentioned process is a process to cut the bond of the porous insulating film 48 having the siloxane bond.

Next, to the first porous insulating film 48, dangling bond termination processing by gas exposure is performed.

First, after the electron beam irradiation, the gas introduction control device 22 opens the valve 20 connected to an ethylene gas supply device (not depicted in the figure). Then, an ethylene gas flows in the processing room 8. The pressure of the processing room 8 is maintained to be 1 Pa, by means of a pressure regulating device and an exhaust pump provided on the downstream side of the vacuum exhaust outlet 16. The introduction of the ethylene gas is continued for 0.5 minutes, and thereafter, the gas introduction control device 22 closes the valve 20. Further, a substrate temperature (that is, the temperature of the porous insulating film 48) at this time is room temperature (25° C.).

By the above-mentioned procedure, the first porous insulating film 48 is exposed to the ethylene gas 50, while the state that the first porous insulating film 48 is shut out of the atmosphere is maintained (refer to FIG. 6F). By the exposure to the ethylene gas, an unpaired bond (dangling bond) being left without rebonded in the first porous insulating film 48 is terminated. As a result, the relative permittivity of the first porous insulating film 48 increased by the insulating film denaturation processing is restored from 2.9 to 2.3. On the other hand, the modulus of elasticity, which is an index of the mechanical strength, is maintained to have a large value of 17 GPa.

As such, by the reception of the insulating film denaturation processing and the dangling bond termination processing, the first porous insulating film 48 becomes a second interlayer insulating film 49.

Now, the effective relative permittivity of the first porous insulating film 48 varies with the processing time as depicted by the solid line in FIG. 1. As illustrated in FIG. 1, when the first porous insulating film 48 is exposed to the ethylene gas, the effective relative permittivity starts to descend, and after 0.5 minutes, reaches a minimum value (=2.6). Thereafter, the effective relative permittivity stays at the minimum value for a period of time, and then starts to ascend at a time point after a lapse of 10 minutes.

Therefore, in the present embodiment, before the time point of the first ascent (10 to 15 minutes) of the relative permittivity, the exposure to the ethylene gas is completed at 0.5 minute. Therefore, the valve 20 is closed after the lapse of 0.5 minute after the introduction of the ethylene gas.

Namely, after the relative permittivity of the first insulating film descends due to the exposure of the first porous insulating film 48 to the ethylene gas, the exposure to the ethylene gas is completed before the time point when the relative permittivity of the first porous insulating film 48 first ascends (refer to FIG. 6G). Here, the effective relative permittivity has a value higher by approximately 0.3 than the relative permittivity. For example, the above minimum value 2.6 corresponds to a relative permittivity of 2.3 (=2.6−0.3).

Next, a second SiC:O:H film 52 having a thickness of 30 nm is formed on the first porous insulating film 48 (refer to FIG. 6H).

Next, using a resist mask corresponding to a wiring groove formed on the second interlayer insulating film 49, the second SiC:O:H film 52 and the first porous insulating film 48, which becomes a second interlayer insulating film 49, are etched by F (fluorine) plasma which is produced by using a mixed gas composed of CF₄ and CHF₃ as a material. By the above etching, a first wiring groove 54 having a width of 100 nm is formed (refer to FIG. 61).

Next, on the wiring groove 54, a TaN layer 56 having a thickness of 10 nm and a Cu layer (not depicted in the figure) having a thickness of 10 nm are formed by sputtering. Here, the TaN 56 acts as a diffusion barrier to prevent Cu from diffusing to the insulating film. Thereafter, by electroplating using the above Cu layer as a seed electrode, Cu 58 is formed to the amount of 600 nm. Thereafter, the Cu outside the wiring groove 54 is removed by CMP (refer to FIG. 6J). By the above processes, a first Cu wiring 60 is formed.

Next, by the CVD method, a first SiN film 62 having a thickness of 30 nm is formed on the first Cu wiring 60 and the second SiC:O:H film 52 (refer to FIG. 6K).

Next, a second porous insulating film 64 having a thickness of 180 nm is formed on the second SiC:O:H film 52. Thereafter, on the second porous insulating film 64, the aforementioned insulating film denaturation processing and the dangling bond termination processing are performed. Further, a third SiC:O:H film 66 having a thickness of 30 nm is formed on the second porous insulating film 64.

Next, a third porous insulating film 68 having a thickness of 160 nm is formed on the third SiC:O:H film 66. Thereafter, on the third porous insulating film 68, the insulating film denaturation processing and the dangling bond termination processing are performed. Further, a fourth SiC:O:H film 70 having a thickness of 30 nm is formed on the fourth porous insulating film 68 (refer to FIG. 6L).

Here, the second and third porous insulating films 64, 68 become the third and fourth interlayer insulating films 72, 74, respectively.

Additionally, each method for forming the second and third porous insulating films 64, 68 is identical to the method for forming the first porous insulating film 48. Also, the insulating film denaturation processing and the dangling bond termination processing performed on the second and third porous insulating films 64, 68 are identical to the insulating film denaturation processing and the dangling bond termination processing performed on the first porous insulating film 48.

Next, using a resist mask corresponding to a via hole which is formed in the third interlayer insulating film 72, the second and third porous insulating films 64, 68 are etched by F (fluorine) plasma which is produced by using a mixed gas composed of CF₄ and CHF₃ as a material. At this time, by adjusting the composition and the pressure of the above mixed gas, the fourth SiC:O:H film 70, the third porous insulating film 68, the third SiC:O:H film 66, the second porous insulating film 64 and the first SiN film 62 are etched successively. By this etching, a via hole 75 is formed (refer to FIG. 6M).

Next, using a resist mask corresponding to the wiring groove which is formed in the fourth interlayer insulating film 74, the fourth SiC:O:H film 70 and the third porous insulating film 68 are etched by F (fluorine) plasma which is produced by using a mixed gas composed of CF₄ and CHF₃ as a material. By this etching, a second wiring groove 76 having a width of 100 nm is formed (refer to FIG. 6M).

Next, on the via hole 75 and the second wiring groove 76, a TaN layer 78 having a thickness of 10 nm and a Cu layer (not depicted in the figure) having a thickness of 10 nm are formed by sputtering. Here the TaN 78 functions as a diffusion barrier to prevent Cu from diffusing to the insulating film. Thereafter, by electroplating using the above Cu layer as a seed electrode, Cu 80 is formed to the amount of 1,400 nm. Thereafter, the Cu outside the second wiring groove 76 is removed by the CMR By the above processes, a second Cu wiring 82 and a second plug 84 are formed. Thereafter, by the CVD method, a second SiN film 86 having a thickness of 30 nm is formed on the second Cu wiring 82 and the fourth SiC:O:H film 70 (refer to FIG. 6N).

By the above-mentioned processes, a semiconductor device having two wiring layers is completed. However, the number of wiring layers is not limited to 2 layers. For example, using the identical processes to the processes to form the third and fourth interlayer insulating films 72, 74, the second plug 84 and the second Cu wiring 82, it may also be possible to form a fifth and a sixth interlayer insulating films, a third plug and a third Cu wiring.

According to the present embodiment, the insulating film denaturation processing is performed on the porous insulating film which becomes the interlayer insulating film. Therefore, because the mechanical strength of the porous insulating film is enhanced, the porous insulating film is not peeled off even CMP is performed to form the wiring groove etc.

Further, the dangling bond termination processing is performed on the porous insulating film which becomes the interlayer insulating film. Accordingly, the increase of the relative permittivity due to the insulating film denaturation processing is suppressed. By this, the inter-wire capacitance becomes small, and the signal delay time of the semiconductor device having such porous insulating films becomes small as well.

Further the dangling bond termination processing performed in the present embodiment is processing only to expose the porous insulating film to the ethylene gas for an extremely short time (0.5 minutes). Therefore, according to the present embodiment, the interlayer insulating film, having enhanced mechanical strength and low permittivity, may be formed in a short time.

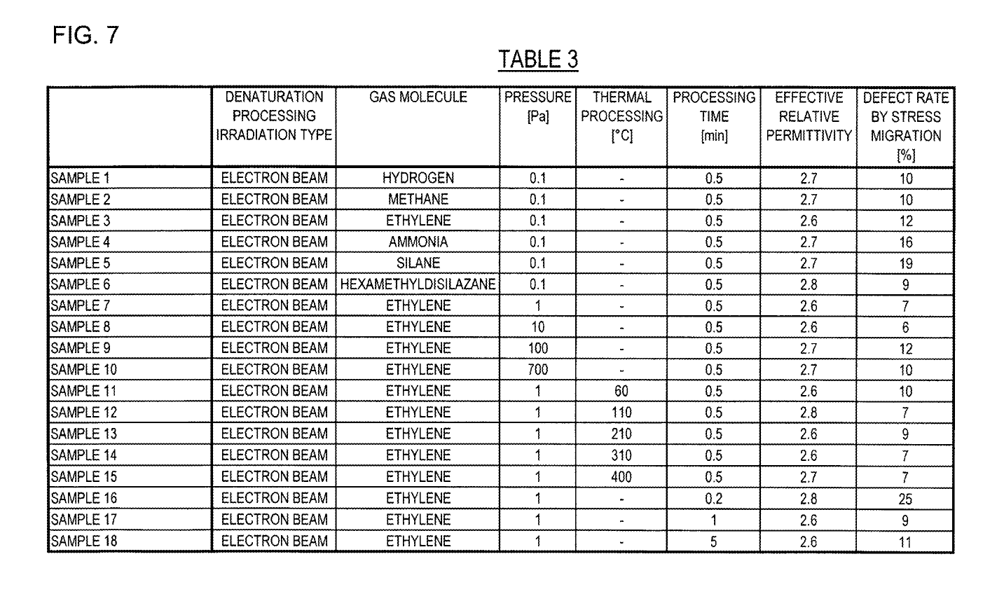

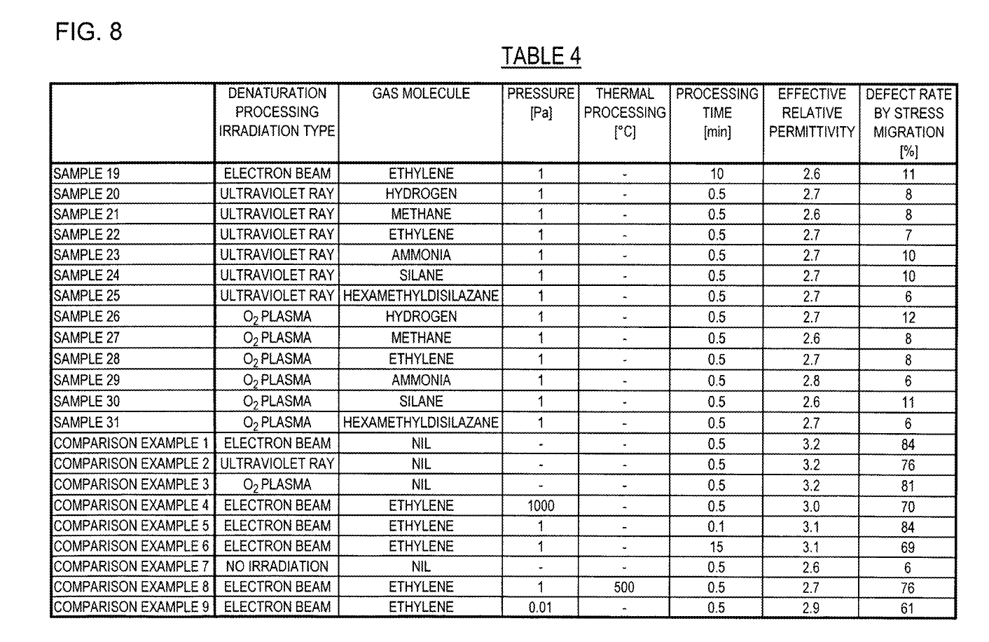

FIGS. 7 and 8 are tables illustrating the properties of the semiconductor device (effective relative permittivity and defect rate due to stress migration) manufactured under a variety of modified conditions of the dangling bond termination processing.

Points of view of the above tables are substantially identical to the points of view of the aforementioned Tables 1 and 2. “Electron beam”, “ultraviolet ray” and “O₂ plasma” represent electron beam irradiation, ultraviolet irradiation and exposure to O₂ plasma, respectively. Also, the respective processing conditions (the irradiation condition of the electron beam etc.) are identical to the conditions described in relation to Tables 1 and 2.

In the third to sixth columns, the conditions of the dangling bond termination processing are described. Meanwhile, the properties obtained by measuring the semiconductor device are described in the seventh and eighth columns. Here, the semiconductor device used for the measurement has substantially identical structure to the semiconductor device described by reference to FIGS. 6A to 6N, except the conditions for the insulating film denaturation processing and the dangling bond termination processing which are performed on the porous insulating film which becomes the interlayer insulating film. However, wiring layers are composed of three layers.

As is apparent by reference to Tables 1 to 4, the conditions for the processing (insulating film denaturation processing and dangling bond termination processing) performed on each sample having an identical name (for example, “sample 1”) are identical.

The method for measuring the effective relative permittivity is as described earlier. However, the measurement of the Cu inter-wire capacitance is performed between wirings which are vertically separated by the interlayer insulating film.

The defect rate due to the stress migration is a proportion of wirings having wiring resistance increased by 50% or more by heating processing. The temperature and the time of the heating processing are 200° C. and 500 hours.

The influence of the insulating film denaturation processing and the dangling bond termination processing upon the effective relative permittivity of the interlayer insulating film is identical to the influence of the respective processing upon the relative permittivity of the insulating film described by reference to Tables 1 and 2 (refer to the seventh column of Tables 1 to 4).

In the eighth column of Tables 3 and 4, the defect rate due to the stress migration is described. The stress migration defect rate in the comparison example 7 on which no such processing is performed is only 6%. In contrast, when the insulating film denaturation processing is performed, the defect rate due to the stress migration abruptly increases to 76 to 84% (refer to the comparison examples 1 to 3). However, when the dangling bond termination processing is performed, the stress migration defect rate is decreased to 6 to 25% (refer to the sample 1 to the sample 31).

Now, as described by reference to Tables 1 and 2, when the insulating film denaturation processing is performed, the internal stress difference of the insulating film increases. It is considered that the increase of the stress migration defect rate due to the insulating film denaturation processing is caused by the above increase of the internal stress difference.

On the other hand, when the dangling bond termination processing is performed after the insulating film denaturation processing, the internal stress difference of the insulating film decreases (refer to each final column of Tables 1 and 2). It is considered that, by the above decrease of the internal stress, the defect rate due to the stress migration is also decreased.

As such, according to the present semiconductor device manufacturing method, the wiring defect due to the stress migration hardly increases even when the insulating film denaturation processing is performed on the insulating film which becomes the interlayer insulating film.

In FIG. 1, the variation of the defect rate due to the stress migration relative to the processing time of the dangling bond termination processing is illustrated by the broken line. The defect rate due to the stress migration varies substantially in the same manner as the relative permittivity which is illustrated by the solid line. This fact indicates that both variations are caused by an identical factor, namely, the disappearance and the regeneration of the dangling bond. Here, the variation of the defect rate due to the stress migration illustrated in FIG. 1 is based on the data described in Tables 3 and 4.

In FIG. 4, the variation of the defect rate due to the stress migration relative to the gas pressure used for the dangling bond termination processing is depicted using the broken line. The defect rate due to the stress migration to the gas pressure also varies substantially in the same manner as the relative permittivity (solid line). The above fact also indicates that both variations are caused by an identical factor, namely, the disappearance and the regeneration of the dangling bond. Here, the variation of the defect rate due to the stress migration illustrated in FIG. 4 is also based on the data described in Tables 3 and 4.

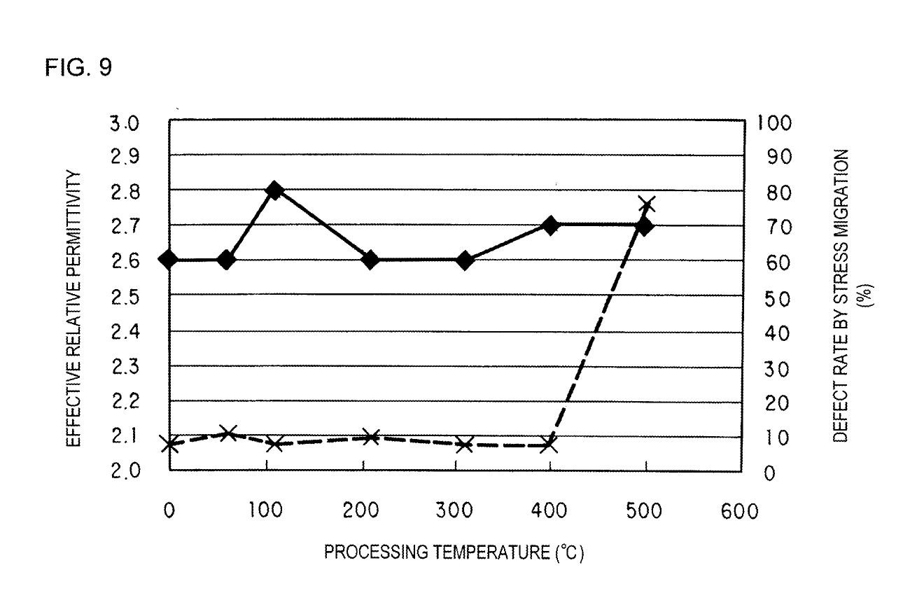

FIG. 9 is a diagram illustrating relationship between the temperature of the dangling bond termination processing and the defect rate (broken line) due to the stress migration. In FIG. 9, the variation of the effective relative permittivity relative to the processing temperature is depicted by the solid line. The horizontal axis illustrates the processing temperature. The right vertical axis illustrates the defect rate due to the stress migration. The left vertical axis illustrates the effective relative permittivity.

The variation of the defect rate illustrated in FIG. 9 is based on the data measured on the samples 7 and 11-15 in Tables 3 and 4.

As illustrated in FIG. 9, the relative permittivity is substantially constant irrespective of the temperature, and however, the defect rate due to the stress migration abruptly increases when the processing temperature exceeds 400° C.

It is considered that the above abrupt increase is caused by that Cu diffused in the insulating film due to an ascent of the processing temperature causes an increased internal stress of the insulating film.

The higher the temperature of the dangling bond termination processing is, the higher the termination processing speed becomes. In particular, when the temperature of the termination processing is 50° C. or more, the increase of the termination processing speed is clearly observed. From this point of view, the ascent of the processing temperature is preferable. However, as illustrated in FIG. 9, if the processing temperature exceeds 400° C., the defect rate due to the stress migration abruptly increases.

Accordingly, when the insulating film is exposed to the gas to perform the dangling bond termination processing, the temperature of the insulating film is preferably 0° C. or more and 400° C. or less, and more preferably 50° C. or more and 300° C. or less, and most preferably 100° C. or more and 200° C. or less. Here, the above heating of the insulating film may be performed by the heating device 14 provided on the sample support stage 12 (refer to FIG. 5).

Now, in the aforementioned process to form the first and second wiring grooves 54, 76 and the via hole 75, the porous insulating films 48, 64, 68 are etched by being exposed to F plasma, after the dangling bond termination processing. Further, the porous insulating films 48, 64, 68 are also exposed to O₂ plasma which is used for ashing processing to remove a resist mask film used in the above reactive ion etching.

Through these processing, the dangling bonds are formed in the vicinity of the etching surface of the porous insulating films 48, 64, 68. To terminate the dangling bonds, after the reactive ion etching by the F plasma and the ashing processing by the O₂ plasma, it is preferable that the dangling bond termination processing is performed before proceeding to the next process.

Namely, the insulating film denaturation processing (first process) may be a process to process the insulating film, instead of the processing to enhance the mechanical strength of the insulating film such as described above. Here the process to process the insulating film is, for example, the process to etch the insulating film by the plasma exposure, or the process to remove a photoresist film formed on the insulating film by the plasma exposure, as described above. Alternatively, the process to process the insulating film may be a process in which both the above-mentioned reactive etching and the ashing processing are performed.

Also, in the above manufacturing method, the energy beam to expose the insulating film thereto is the electron beam. However, the energy beam to expose the insulating film may be the ultraviolet ray.

### Embodiment 2

The present embodiment relates to the semiconductor device manufacturing method in which the bond of the insulating film is cut by the exposure to the plasma.

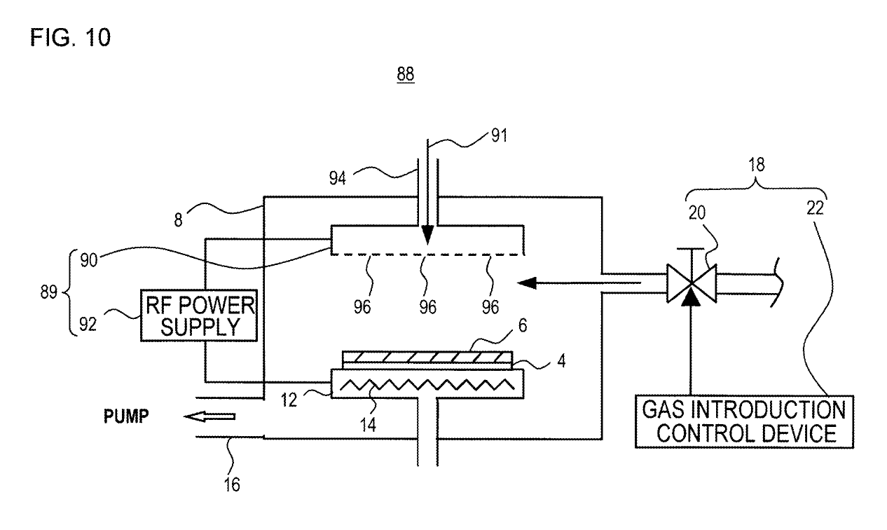

FIG. 10 is a diagram illustrating the configuration of a manufacturing apparatus 88 used in the present embodiment. The configuration of the present manufacturing apparatus 88 is identical to the manufacturing apparatus 2 in the embodiment 1, which is described by reference to FIG. 5, excluding a point that a plasma generation device 89 is provided in place of the energy beam generation device 10. Therefore, the following description is given in regard to the relevant point of difference.

The present plasma generation device 89 includes a counter electrode 90 disposed opposite to the sample support stage 12, and a radio frequency power supply 92 (RF power supply) for applying a radio frequency wave between the counter electrode 90 and the sample support stage 12.

Also, on the counter electrode 90, a gas introduction inlet 94 for supplying a material gas 91 (for example, O₂ gas) for plasma is provided. Further, an ejection outlet 96 for ejecting the above gas internally to the processing room 8 is provided on the counter electrode 90.

The plasma material gas is supplied from the ejection outlet internally to the processing room 8, and exhausted via the vacuum exhaust outlet 16. At this time, the inside of the processing room 8 is maintained at a constant pressure by means of a pressure regulating device (not depicted in the figure). In this state, plasma is generated when the radio frequency power supply 92 applies radio frequency power between the counter electrode 90 and the sample support stage 12.

By the exposure to the plasma, the bonds in the insulating film 6 are cut. As a result, the mechanical strength of the insulating film 6 is enhanced.

Here, a material gas for plasma is, for example, O₂ gas and H₂ gas. In addition, the radio frequency power supplied from the radio frequency power supply 92 is 200 W, for example. Also, the pressure of the material gas 91 during plasma generation is 10 Pa, for example.

When the insulating film is exposed to the plasma in such a manner, the modulus of elasticity of the insulating film increases, similar to the exposure to the energy beam (refer to the comparison example 3 in Table 2). In other words, the mechanical strength of the insulating film is also enhanced by the exposure to the plasma. Further, the relative permittivity of the insulating film also increases. Here, it is considered that the enhancement of the mechanical strength of the insulating film is caused by that electrons and ions in the plasma cut the bonds in the insulating film.

The semiconductor device manufacturing method according to the present embodiment is substantially identical to the semiconductor device manufacturing method according to the embodiment 1, except for a point that the insulating film denaturation processing is performed using the above-mentioned manufacturing apparatus 88.

In Tables 3 and 4, the properties of the semiconductor device manufactured by using the O₂ plasma are also described (samples 26 to 31 and comparison example 3).

According to the present embodiment, it is possible to suppress the permittivity of the insulating film increased by the exposure to the O₂ plasma, by a short-time exposure to an ethylene gas etc (refer to Tables 3 and 4).

The results described in Tables 1 to 4 represent that, as insulating film denaturation processing (for enhancing the mechanical strength), ultraviolet irradiation and exposure to plasma are effective, similar to the known electron beam irradiation.

As compared to an electron beam irradiation source, no high voltage source is used in the device for use in the above insulating film denaturation processing, and therefore, the configuration is simple and the cost is low. Also, differently from the electron beam irradiation, the ultraviolet irradiation and the plasma exposure are excellent in a point that a small damage is produced on an electronic device formed on the Si substrate which acts as a foundation.

(Deformation example)

The aforementioned example is the semiconductor device manufacturing method in which the insulating film is formed by sintering the liquid composition, including the silicon compound, manufactured from TAOS and AS as materials, and the insulating film denaturation processing and the dangling bond termination processing are performed on the insulating film.

However, the insulating film to be used to manufacture the present semiconductor device is not limited to such an insulating film.

For example, it is also possible that the liquid composition which becomes the insulating film by the sintering may be a composition including such a silicon compound as described below. The silicon compound (A) of interest is a silicon compound obtained by mixing an intermediate, which is obtained after hydrolyzing or partially hydrolyzing TAOS under the existence of TAAOH, with AS or the hydrolysate thereof or the partial hydrolysate. Alternatively, the silicon compound (A) is a silicon compound obtained by hydrolyzing a portion or the entire silicon compound obtained by the above mixture.

Here, TAOS is tetraalkylorthosilicate, and TAAOH is tetraalkylammoniumhydroxide. Also AS is alkoxysilane expressed by the following general formula (II).

XₙSi(OR)₄₋ₙ (II)

Here, X represents any one of hydrogen atom, fluorine atom, alkyl group with the carbon number of 1 to 8, fluorine-substituted alkyl group, aryl group and vinyl group. Also, R represents any one of hydrogen atom, alkyl group with the carbon number of 1 to 8, aryl group and vinyl group. Further, n is an integer of 0 to 3.

Additionally, such an insulating film is so-called nanoclustering silica (NCS) having a nano-sized hole (with a diameter of 1 nm to 10 nm), similar to the insulating film described above.

Further, the insulating film used to manufacture the present semiconductor device may be an insulating film containing silicon and oxygen as principal components (SiO-containing insulating film), or maybe an insulating film containing silicon, oxygen and carbon as principal components (SiOC-containing insulating film). Alternatively, the above insulating film may be an insulating film containing silicon, oxygen, carbon and hydrogen as principal components (SiOCH-containing insulating film), or maybe an insulating film containing silicon, oxygen, carbon and nitrogen as principal components (SiOCN-containing insulating film). Further, alternatively, the above insulating film maybe an insulating film containing silicon, oxygen, carbon, nitrogen and hydrogen, as principal components (which may be referred to as SiOCNH-containing insulating film). The meaning of “as principal components” is that the other components may be coexistent to the extent of not damaging the function of the insulating film.

The SiO-containing insulating film is an insulating film having an atomic composition ratio close to SiO₂. The aforementioned nanoclustering silica (having a relative permittivity of approximately 2.25) is a kind of the SiO-containing insulating film. Further, a porous carbon doped SiO₂ film (having a relative permittivity of approximately 2.5), which is formed by adding a heat decomposable compound to a carbon doped SiO₂ film, and further by heat decomposing the above heat decomposable compound, is also a kind of the SiO-containing insulating film.

An insulating film manufactured by use of polycarbosilane or polycarboxysilane as materials is also a kind of the SiOC-containing insulating film or the SiOCH-containing insulating film. Further, an organic or inorganic SOG (spinon glass; the relative permittivity is approximately 2.7) is a kind of the SiOC-containing insulating film or the SiOCH-containing insulating film.

Further, as the SiOCN-containing insulating film or the SiOCHN-containing insulating film, for example, a SiOCHN-containing insulating film such as a SiC:N film (having a relative permittivity of approximately 7) produced by CVD is known.

From the viewpoint of an interaction between with moisture, it is more preferable to apply the present embodiments when the SiOC-containing insulating film, the SiOCH-containing insulating film or the SiOCHN-containing insulating film is used, because Si—OH group is apt to be generated at that time. It is particularly preferable to apply the present embodiments when the silicon insulating film is the SiOCH-containing insulating film.

According to the present semiconductor device manufacturing method, the dangling bond termination processing is performed on the insulating film while the insulating film is kept shut out of the atmosphere, after the insulating film undergoes the insulating film denaturation processing. However, it may be possible for the insulating film to undergo the dangling bond termination processing after being once exposed to the atmosphere, if it takes a short time.

Further, the gas for use in the dangling bond termination processing may be other gas than the aforementioned gas (ethylene gas, for example), such as a gas having halogen as constituent element, for example like a NF₃ gas.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A semiconductor device manufacturing method comprising:
irradiating an insulating film including a siloxane bond with an energy beam or plasma; and
exposing the insulating film to a gas including at least one element selected from the group consisting of hydrogen, carbon, nitrogen and silicon excluding N₂ or H₂O gases,
wherein said exposing the insulating film to the gas is finished before a time point when a relative permittivity of the insulating film first ascends after the relative permittivity descends by said exposing the insulating film to the gas.

2. The semiconductor device manufacturing method according to claim 1,
wherein exposure time of the insulating film to the gas is 0.5 minute or more and 10 minutes or less.

3. The semiconductor device manufacturing method according to claim 1,
wherein gas pressure during said exposing the insulating film to the gas is 0.05 Pa or more and 700 Pa or less.

4. The semiconductor device manufacturing method according to claim 1,
wherein the insulating film is an interlayer insulating film where a wiring is formed, and
a temperature of the insulating film in the exposing to the gas is 0° C. or more and 400° C. or less.

5. The semiconductor device manufacturing method according to claim 1,
wherein the gas is a gas selected from the group consisting of hydrogen, methane, ethylene, ammonia, silane and hexamethyldisilazane.

6. The semiconductor device manufacturing method according to claim 1, wherein the energy beam is an electron beam or an ultraviolet ray.

7. The semiconductor device manufacturing method according to claim 1,
wherein the exposing to the gas is a process to enhance mechanical strength of the insulating film.

8. The semiconductor device manufacturing method according to claim 1,
wherein the exposing to the gas is a process to process the insulating film.

9. The semiconductor device manufacturing method according to claim 8,
wherein the exposing to the gas is one or both of a process to etch the insulating film by the exposure thereof to plasma and a step to remove a photoresist film formed on the insulating film by the exposure thereof to plasma.

10. The semiconductor device manufacturing method according to claim 1,
wherein the relative permittivity of the insulating film is 2.7 or less and 2.0 or more.

11. The semiconductor device manufacturing method according to claim 1,
wherein the insulating film is an insulating film formed by coating a liquid composition including a silicon compound on a semiconductor substrate, and by sintering the coated liquid composition.

12. The semiconductor device manufacturing method according to claim 11,
wherein the silicon compound is a silicon compound obtained by hydrolyzing tetraalkylorthosilicate (TAOS) and alkoxysilane (AS) represented by the following general formula (I) under existence of tetraalkylammoniumhydroxide (TAAOH).
XₙSi(OR)₄₋ₙ (I)
(in the formula, X represents hydrogen atom, fluorine atom, alkyl group with a carbon number of 1 to 8, fluorine-substituted alkyl group, aryl group or vinyl group, and R represents hydrogen atom, alkyl group with a carbon number of 1 to 8, aryl group or vinyl group. Further, n is an integer of 0 to 3.)

13. The semiconductor device manufacturing method according to claim 11,
wherein the silicon compound is a silicon compound obtained by mixing an intermediate being obtained after hydrolyzing or partially hydrolyzing tetraalkylorthosilicate (TAOS) under existence of tetraalkylammoniumhydroxide (TAAOH), with alkoxysilane (AS) represented by the following general formula (II) or a hydrolysate or a partial hydrolysate of the alkoxysilane, or by hydrolyzing a portion or the entire of the silicon compound.
XₙSi(OR)₄₋ₙ (II)
(in the formula, X represents hydrogen atom, fluorine atom, alkyl group with a carbon number of 1 to 8, fluorine-substituted alkyl group, aryl group or vinyl group, and R represents hydrogen atom, alkyl group with a carbon number of 1 to 8, aryl group or vinyl group. Further, n is an integer of 0 to 3.)

14. A semiconductor device manufacturing method comprising:
cutting a bond of an insulating film including a siloxane bond; and
exposing the insulating film to a gas including at least one element selected from the group consisting of hydrogen, carbon, nitrogen and silicon excluding nitrogen or H₂O gases,
wherein said exposing the insulating film to the gas is finished before a time point when a relative permittivity of the insulating film first ascends after the relative permittivity descends by the exposing the insulating film to the gas.

15. A semiconductor device manufacturing apparatus comprising:
a processing room including a generation device configured to generate an energy beam or plasma to which an insulating film is irradiated; and
a gas introduction device configured to introduce a gas including at least one element selected from the group consisting of hydrogen, carbon, nitrogen and silicon excluding N₂ or H₂O gases to the processing room, wherein the gas introduction device is configured to finish introducing the gas before a time point when a relative permittivity of the insulating film first ascends after the relative permittivity of the insulating film descends.

16. A semiconductor device manufacturing apparatus according to claim 15,
wherein the energy beam is an electron beam or an ultraviolet ray.

17. The semiconductor device manufacturing apparatus according to claim 15,
wherein the gas is a gas selected from the group consisting of hydrogen, methane, ethylene, ammonia, silane and hexamethyldisilazane.
